(19) United States
(12) Patent Application Publication
(10) Pub. No.: US 2024/0421542 A1
(43) Pub. Date: Dec. 19, 2024

(54) Connector Shielding Shell, Connector Shielding Shell Assembly, Connector and Shell Part

(71) Applicants: TE Connectivity India Private Limited, Bangalore (IN); Tyco Electronics (Shanghai) Co., Ltd., Shanghai (CN)

(72) Inventors: WenYu (Vindy) Liu, Shanghai (CN); Guangming (Suny) Zhao, Shanghai (CN); Yang (Eric) Shi, Shanghai (CN); Remesh Kuzhikkali, Bangalore (IN)

(73) Assignees: TE Connectivity India Private Limited, Bangalore (IN); Tyco Electronics (Shanghai) Co., Ltd., Shanghai (CN)

(21) Appl. No.: 18/742,256

(22) Filed: Jun. 13, 2024

(30) Foreign Application Priority Data
Jun. 16, 2023 (CN) 202310721621.8

(51) Int. Cl. H01R 13/659

(52) U.S. Cl. CPC H01R 13/659

(57) ABSTRACT

A connector shielding shell includes a bottom shell and a top shell. The top shell has a top wall having a predetermined thickness. An installation opening is formed on or in the top wall and is adapted to receive a cooling pipe. The top shell defines a cooling plate adapted to transfer heat to the cooling pipe.

### CROSS-REFERENCE TO RELATED APPLICATION

This application claims the benefit of Chinese Patent Application No. CN202310721621.8 filed on Jun. 16, 2023, in the State Intellectual Property Office of China, the whole disclosure of which is incorporated herein by reference.

### FIELD OF THE INVENTION

Embodiments of the present disclosure relate to a connector shielding shell, and a shell part for assembling the connector shielding shell. The present disclosure also relates to a connector shielding shell assembly comprising the connector shielding shell, and a connector comprising the connector shielding shell assembly.

### BACKGROUND

In the prior art, a high-speed connector generates a large amount of heat. Accordingly, the connector typically requires the installation of finned heat sink on a top wall of an outer shielding shell (usually referred to as the iron cage) of the connector. However, for high-speed connector with multiple chambers, it is necessary to install thermal pads, thermal bridges, cooling plates, and cooling pipes on the outer connector shielding shell to further improve heat dissipation performance. The existing cooling scheme requires numerous components, which increases the contact thermal resistance and leads to a decrease in heat dissipation performance. In addition, in the prior art, it is necessary to install cooling plates and cooling pipes on the side of the outer shielding shell. This occupies a side space of the outer shielding, resulting in a decrease in the layout density of the chambers.

### SUMMARY

According to an embodiment of the present disclosure, a connector shielding shell includes a bottom shell and a top shell. The top shell has a top wall having a predetermined thickness. An installation opening is formed on or in the top wall and is adapted to receive a cooling pipe. The top shell defines a cooling plate adapted to transfer heat to the cooling pipe.

### BRIEF DESCRIPTION OF THE DRAWINGS

The invention will now be described by way of example with reference to the accompanying Figures, of which:

FIG. 1 shows an illustrative perspective view of a connector shielding shell assembly according to a first embodiment of the present invention;

FIG. 2 shows an illustrative exploded view of the connector shielding shell assembly shown in FIG. 1;

FIG. 3 shows an illustrative perspective view of the top shell of the connector shielding shell assembly shown in FIG. 1 when viewed from the bottom;

FIG. 4 shows an illustrative view of the top shell, thermal conductivity component, and cooling pipe of the connector shielding shell assembly shown in FIG. 1;

FIG. 5 shows an illustrative perspective view of a connector shielding shell assembly according to a second embodiment of the present invention;

FIG. 6 shows an illustrative exploded view of the connector shielding shell assembly shown in FIG. 5;

FIG. 7 shows an illustrative perspective view of a connector shielding shell assembly according to a third embodiment of the present invention;

FIG. 8 shows an illustrative exploded view of the connector shielding shell assembly shown in FIG. 7; and

FIG. 9 shows an illustrative perspective view of the top shell of the connector shielding shell assembly shown in FIG. 7 when viewed from the bottom.

### DETAILED DESCRIPTION OF THE EMBODIMENTS

Exemplary embodiments of the present disclosure will be described hereinafter in detail with reference to the attached drawings, wherein the like reference numerals refer to the like elements. The present disclosure may, however, be embodied in many different forms and should not be construed as being limited to the embodiment set forth herein; rather, these embodiments are provided so that the present disclosure will be thorough and complete, and will fully convey the concept of the disclosure to those skilled in the art.

In the following detailed description, for purposes of explanation, numerous specific details are set forth to provide a thorough understanding of the disclosed embodiments. It will be apparent, however, that one or more embodiments may be practiced without these specific details. In other instances, well-known structures and devices are schematically shown to simplify the drawing.

According to an embodiment of the present disclosure, a connector shielding shell comprises a bottom shell and a top shell which includes a top wall with a predetermined thickness. An installation slot or an installation hole is formed on or in the top wall of the top shell for installing a cooling pipe. The top shell is used as a cooling plate to transfer heat to a cooling pipe.

According to another embodiment, a connector shielding shell comprises multiple shell parts which are assembled. At least one shell part is formed with an installation slot or an installation hole for installing a cooling pipe. In this way, the at least one shell part is used as a cooling plate to transfer heat to the cooling pipe.

According to embodiment, a connector shielding shell assembly comprises the above connector shielding shell, and a cooling pipe which is installed in the installation slot or the installation hole of the connector shielding shell.

In another embodiment of the present disclosure, a connector comprises the above connector shielding shell assembly, and multiple terminal modules. The multiple terminal modules are respectively installed in multiple chambers of the connector shielding shell and are adapted to mate and connect with mating connectors inserted into the chambers.

The disclosure also includes a shell part for assembling a connector shielding shell. An installation slot or an installation hole is formed on or in the shell part for installing a cooling pipe. The shell part is adapted for use as a cooling plate to transfer heat to the cooling pipe.

### First Embodiment

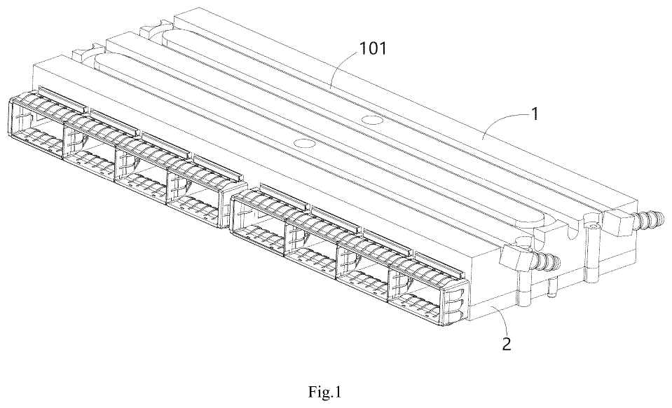

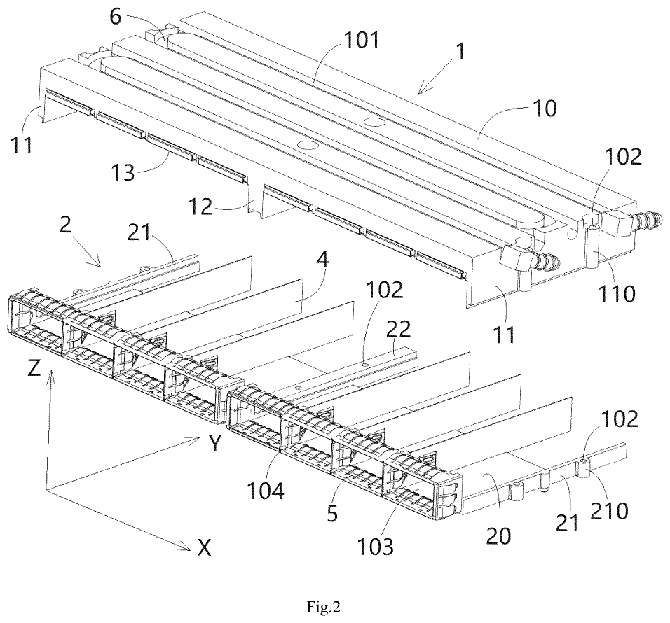

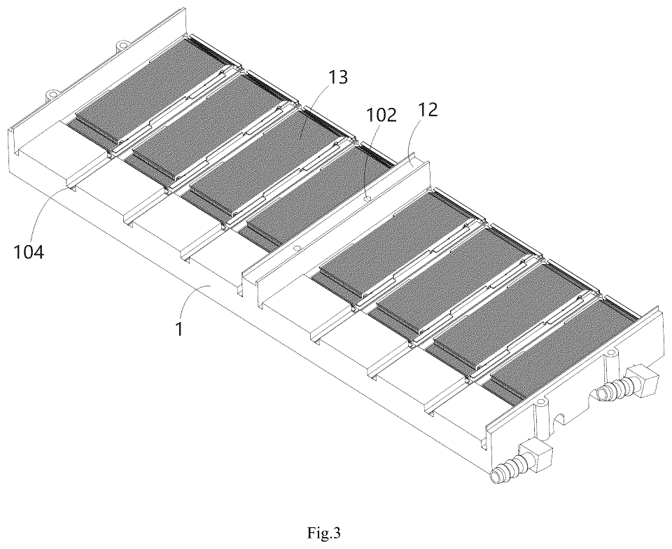

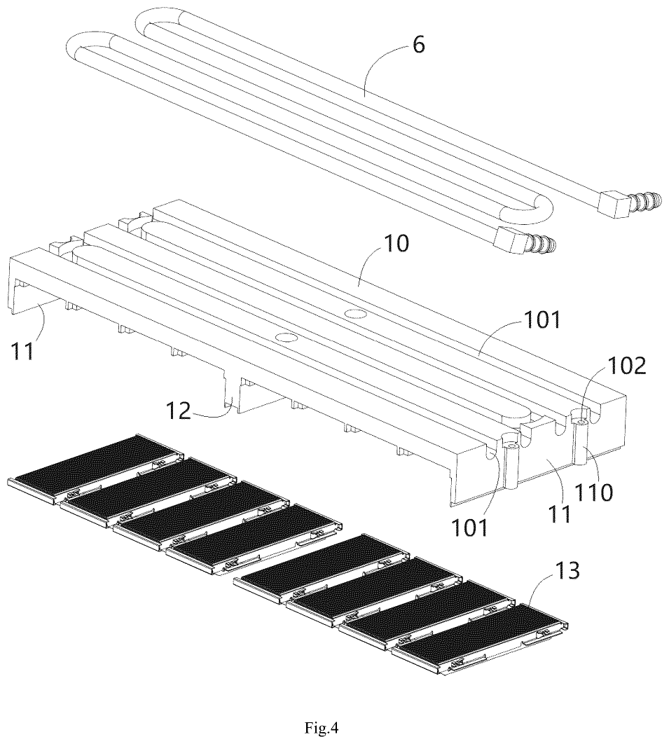

FIGS. 1-4 show a connector shielding shell assembly according to the first embodiment of the present disclosure, wherein FIG. 1 shows an illustrative perspective view of the connector shielding shell assembly according to the first embodiment of the present disclosure. FIG. 2 shows an illustrative exploded view of the connector shielding shell assembly shown in FIG. 1. FIG. 3 shows an illustrative perspective view of the top shell 1 of the connector shielding shell assembly shown in FIG. 1 when viewed from the bottom. FIG. 4 shows an illustrative view of the top shell 1, the thermal conductive component 13 and the cooling pipe 6 of the connector shielding shell assembly shown in FIG. 1.

As shown in FIGS. 1-4, in an exemplary embodiment of the present disclosure, a connector shielding shell is disclosed. The connector shielding shell mainly includes a top shell 1 and a bottom shell 2. The top shell 1 includes a top wall 10 with a predetermined thickness. On the top wall 10 of the top shell 1, an installation slot 101 is formed for installing a cooling pipe 6. Therefore, the top shell 1 is used as a cooling plate to transfer heat to the cooling pipe 6. In the present disclosure, as the cooling plate is directly integrated on the top shell 1, the number of cooling components is reduced, the contact thermal resistance is reduced, and the heat dissipation performance of the connector is improved. In addition, the cooling pipe 6 is installed on the top shell 1, so it does not need to occupy the side space of the connector shielding shell, thereby improving the layout density of the chambers 103 in the connector shielding shell.

The thickness of the top wall 10 of the top shell 1 is greater than a diameter of the cooling pipe 6. The installation slot 101 is formed on the outer surface of the top wall 10 of the top shell 1, which extends along a transverse direction X of the connector shielding shell. The cross-section of the installation slot 101 is U-shaped. The depth of the installation slot 101 is not less than the diameter of the cooling pipe 6, so that the cooling pipe 6 can be completely buried or arranged within the installation slot 101.

In the illustrated embodiments, the top housing 1 can be detachably assembled on the bottom shell 2. The connector shielding shell also includes a vertical partition plate 4, which is set between the top shell 1 and the bottom shell 2 and extends along the longitudinal direction Y and the height direction Z of the connector shielding shell. The vertical partition plate 4 is used to separate the space between the top shell 1 and the bottom shell 2 into multiple chambers 103 arranged side by side in the transverse direction X of the connector shielding shell. In the illustrated embodiment, the connector shielding shell has a single layer of chambers 103.

The top shell 1 also has two first side walls 11 opposite to each other in the transverse direction X of the connector shielding shell, and a first connection column 110 is formed on each of the two first side walls 11. The bottom shell 2 includes a bottom wall and two second side walls 21 opposite to each other in the transverse direction X of the connector shielding shell, and a second connection column 210 is formed on each of the two second side walls 21. A threaded hole 102 is formed in each of the first connection column 110 and the second connection column 210, so that the top shell 1 and the bottom shell 2 can be tightened together by a screw screwed into the threaded holes 102.

A first convex rib 12 extending along the longitudinal direction Y of the connector shielding shell is formed on the inner side of the top shell 1. A second convex rib 22 extending along the longitudinal direction Y of the connector shielding shell is formed on the inner side of the bottom shell 2. The first convex rib 12 and the second convex rib 22 are located in the middle of the transverse direction X of the connector shielding shell. A threaded hole 102 is formed in each of the first convex rib 12 and the second convex rib 22, so that the top shell 1 and the bottom shell 2 can be tightened together by a screw screwed into the threaded holes 102. In this way, the top shell 1 and bottom shell 2 can be more reliably fixed together to prevent separation in the middle of the top shell 1 and bottom shell 2.

In the illustrated embodiments, an insertion slot 104 extending along the longitudinal direction Y of the connector shielding shell is formed on the inner side of each of the top shell 1 and the bottom shell 2. The upper and lower sides of the vertical partition plate 4 are respectively inserted into the insertion slots 104 on the top shell 1 and the bottom shell 2 to fix the vertical partition plate 4 to the top shell 1 and the bottom shell 2.

The connector shielding shell further comprises multiple thermal conductive components 13. The thermal conductive components 13 are respectively arranged in multiple chambers 103 and welded to the inner side of the top shell 1. The thermal conductive component 13 protrudes from the inner side of the top shell 1 to a predetermined height for thermal contact with a mating connector (not shown) inserted into the chamber 103. Thermal conductive component 13 can be a thermal bridge with excellent thermal conductivity performance.

The chamber 103 has an insertion port that allows for the insertion of the mating connector. The connector shielding shell also includes a shielding spring 5. The shielding spring 5 is installed on the peripheral wall of the insertion port of the chamber 103 and is used for electrical contact with a shielding shell of the mating connector.

Still referring to FIGS. 1-4, in another exemplary embodiment of the present disclosure, a connector shielding shell assembly is also provided. The connector shielding shell assembly includes the aforementioned connector shielding shell and a cooling pipe 6. The cooling pipe 6 is installed in the installation slot 101 of the connector shielding shell.

In another exemplary embodiment of the present disclosure, a connector is also disclosed. The connector includes the aforementioned connector shielding shell assembly and multiple terminal modules. The multiple terminal modules are respectively installed in multiple chambers 103 of the connector shielding shell for mating and connecting with the mating connectors inserted in the chambers 103.

### Second Embodiment

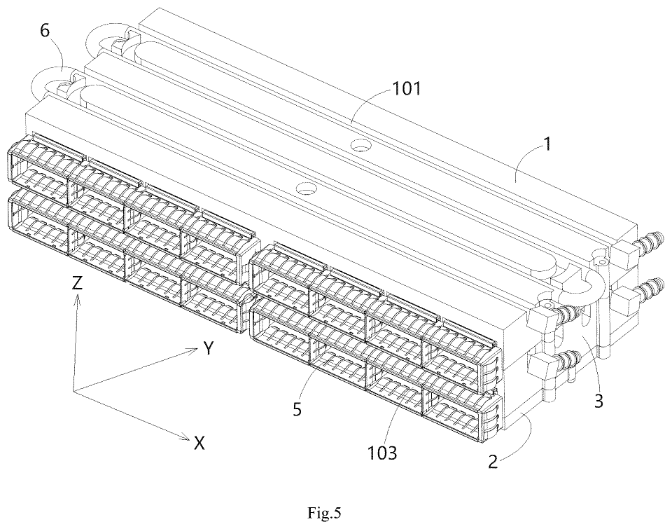

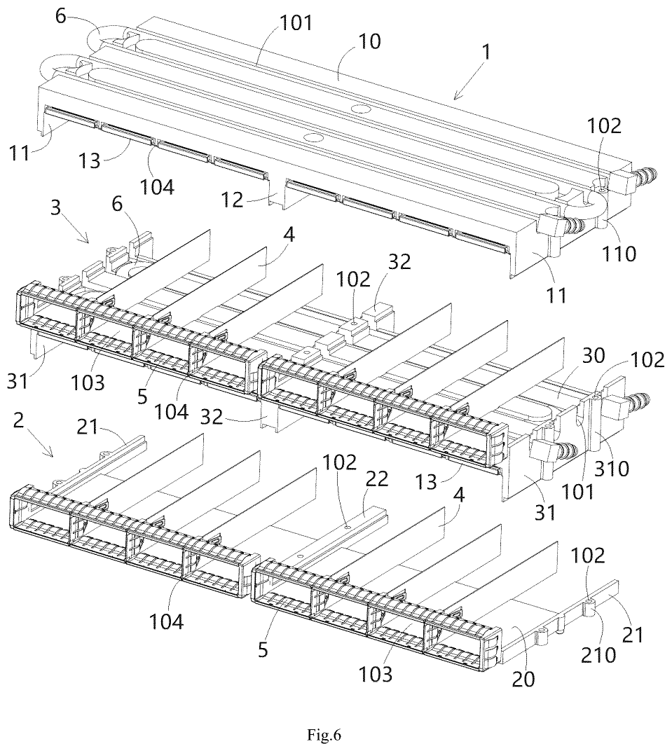

FIGS. 5 and 6 show a connector shielding shell assembly according to a second embodiment of the present disclosure. Specifically, FIG. 5 shows an illustrative perspective view of the connector shielding shell assembly according to the second embodiment of the present invention. FIG. 6 shows an illustrative exploded view of the connector shielding shell assembly shown in FIG. 5.

In an exemplary embodiment of the present disclosure, a connector shielding shell mainly includes a top shell 1, a bottom shell 2, and an intermediate shell 3. The top shell 1 includes a top wall 10 with a predetermined thickness. On the top wall 10 of the top shell 1, an installation slot 101 is formed for installing the cooling pipe 6. Therefore, the top shell 1 is used as a cooling plate to transfer heat to the cooling pipe 6.

The intermediate shell 3 is provided between the top shell 1 and the bottom shell 2 to separate the space between the top shell 1 and the bottom shell 2 into adjacent multi-layer spaces in the height direction Z of the connector shielding shell. The intermediate shell 3 has a horizontal partition wall 30 that separates adjacent two layers of space, and an installation slot 101 or an installation hole 101′ is formed on or in the horizontal partition wall 30 of the intermediate shell 3 for installing the cooling pipe 6. The intermediate shell 3 is used as a cooling plate to transfer heat to the cooling pipe 6.

As the cooling plates are directly integrated on the top shell 1 or the intermediate shell 3, embodiments of the present disclosure reduce the number of cooling components, reduce contact thermal resistance, and improve the heat dissipation performance of the connector. In addition, the cooling pipes 6 is installed on the top shell 1 or the intermediate shell 3, so it does not need to occupy the side space of the connector shielding shell. This improves the layout density of the chambers 103 in the connector shielding shell.

A thickness of the horizontal partition wall 30 of the intermediate shell 3 is greater than the diameter of the cooling pipe 6. An installation slot 101 is formed on the horizontal partition wall 30 of the intermediate shell 3, which extends along the transverse direction X of the connector shielding shell. The cross-section of the installation slot 101 is U-shaped, and the depth of the installation slot 101 is not less than the diameter of the cooling pipe 6. In this way, the cooling pipe 6 can be completely buried or contained in the installation slot 101.

In the illustrated embodiments, the top shell 1, the intermediate shell 3, and the bottom shell 2 can be detachably assembled by stacking them above and below. The connector shielding shell also includes a vertical partition plate 4, which is set in each layer of the multi-layer space and extends along the longitudinal direction Y and the height direction Z of the connector shielding shell. The vertical partition plate 4 is used to divide each layer of space into multiple chambers 103 arranged side by side in the transverse direction X of the connector shielding shell.

The top shell 1 also has two first side walls 11 opposite to each other in the transverse direction X of the connector shielding shell. A first connection column 110 is formed on each of the two first side walls 11. The bottom shell 2 includes a bottom wall and two second side walls 21 opposite to each other in the transverse direction X of the connector shielding shell, and a second connection column 210 is formed on each of the two second side walls 21. The intermediate housing 3 also has two third side walls 31 opposite to each other in the transverse direction X of the connector shielding shell. A third connection column 310 is formed on each of the two third side walls 31. A threaded hole 102 is formed in each of the first connection column 110, the second connection column 210 and the third connection column 310, so that the top shell 1, the bottom shell 2 and the intermediate shell 3 can be tightened together by a screw screwed into the threaded holes 102.

A first convex rib 12 extending along the longitudinal direction Y of the connector shielding shell is formed on the inner side of the top shell 1. A second convex rib 22 extending along the longitudinal direction Y of the connector shielding shell is formed on the inner side of the bottom shell 2. A third convex rib 32 extending along the longitudinal direction Y of the connector shielding shell is formed on the inner side of the intermediate housing 3. The first convex rib 12, the second convex rib 22 and the third convex rib 32 are located in the middle of the transverse direction X of the connector shielding shell, and a threaded hole 102 is formed on each of the first convex rib 12, the second convex rib 22 and the third convex rib 32, so that the top shell 1, the bottom shell 2 and the intermediate shell 3 can be tightened together by a screw screwed into the threaded holes 102.

Insertion slots 104 extending along the longitudinal direction Y of the connector shielding shell are formed on the inner sides of the top shell 1, the bottom shell 2 and the intermediate shell 3, respectively. The side edges of the vertical partition plate 4 are inserted into the insertion slots 104 to fix the vertical partition plate 4.

The connector shielding shell further comprises multiple thermal conductive components 13, which are respectively arranged in multiple chambers 103 of the connector shielding shell. The thermal conductive components 13 located in the top layer of chambers 103 are welded to the inner side of the top shell 1 and protrude at a predetermined height from the inner side of the top shell 1 for thermal contact with the mating connectors inserted into the top layer of chambers 103. The thermal conductive component 13 located in other chambers 103 except for the top layer of chambers 103 are welded to the inner side of the intermediate shell 3 facing the bottom shell 2 and protrude at a predetermined height from the inner side of the intermediate shell 3 for thermal contact with the mating connectors inserted into other chambers 103.

In the illustrated embodiments, the chamber 103 has an insertion port that allows for the insertion of the mating connector. The connector shielding shell also includes a shielding spring 5. The shielding spring 5 is installed on the peripheral wall of the insertion port of the chamber 103 for electrical contact with the shielding shell (not shown) of the mating connector.

In another exemplary embodiment of the present disclosure, a connector shielding shell assembly is also disclosed. The connector shielding shell assembly includes the aforementioned connector shielding shell and a cooling pipe 6. The cooling pipe 6 is installed in the installation slot 101 of the connector shielding shell.

In another exemplary embodiment of the present disclosure, a connector is also provided. The connector includes the aforementioned connector shielding shell assembly and multiple terminal modules. The multiple terminal modules are respectively installed in multiple chambers 103 of the connector shielding shell for mating and connecting with the mating connectors inserted into the chambers 103.

### Third Embodiment

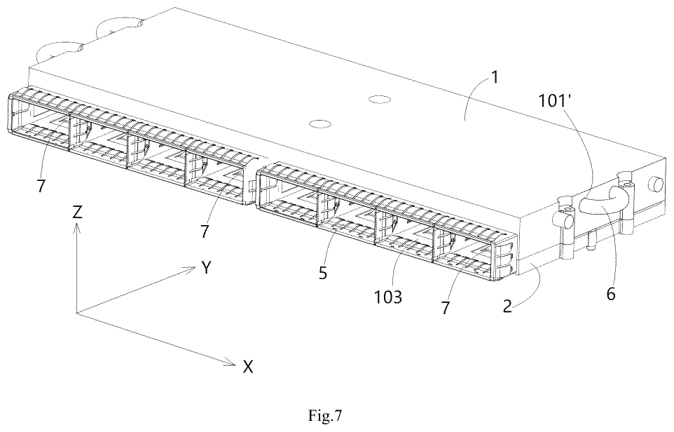

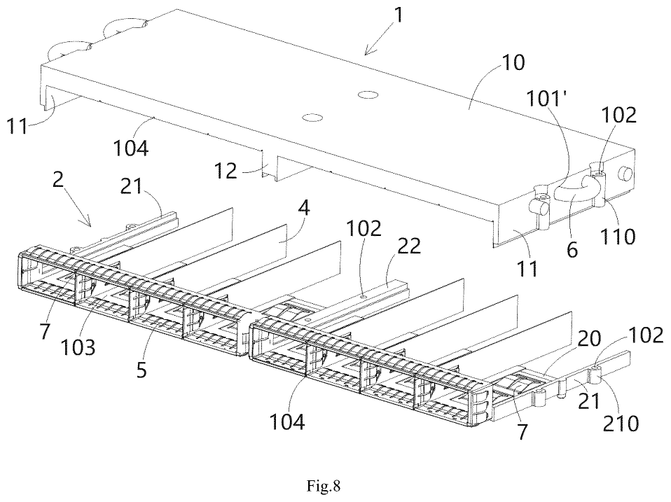

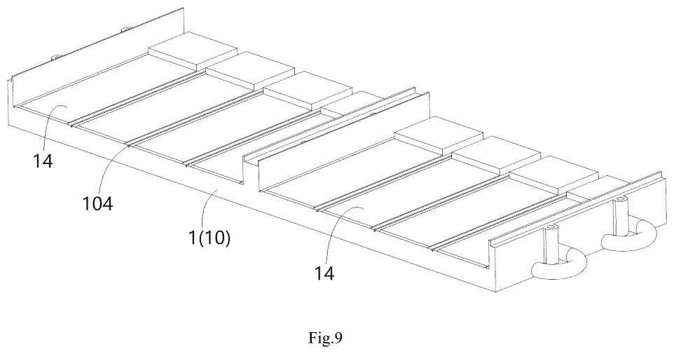

FIGS. 7-9 show a connector shielding shell assembly according to a third embodiment of the present disclosure. Specifically, FIG. 7 shows an illustrative perspective view of the connector shielding shell assembly according to the third embodiment of the present disclosure. FIG. 8 shows an illustrative exploded view of the connector shielding shell assembly shown in FIG. 7. FIG. 9 shows an illustrative perspective view of the top shell 1 of the connector shielding shell assembly shown in FIG. 7 when viewed from the bottom.

With reference to FIGS. 7-9, a connector shielding shell mainly includes a top shell 1 and a bottom shell 2. The top shell 1 includes a top wall 10 with a predetermined thickness. An installation hole 101′ is formed in the top wall 10 of the top shell 1 for installing the cooling pipe 6. Therefore, the top shell 1 is used as a cooling plate to transfer heat to the cooling pipe 6. In the present disclosure, as the cooling plate is directly integrated on the top shell 1, the number of cooling components is reduced, the contact thermal resistance is reduced, and the heat dissipation performance of the connector is improved. In addition, the cooling pipe 6 is installed on the top shell 1, so it does not need to occupy the side space of the connector shielding shell. This improves the layout density of the chamber 103 in the connector shielding shell.

In the illustrated embodiments, the thickness of the top wall 10 of the top shell 1 is greater than the diameter of the cooling pipe 6. The installation hole 101′ is formed in the top wall 10 of the top shell 1, which extends along the transverse direction X of the connector shielding shell. The cooling pipe 6 is inserted into the installation hole 101′.

The top housing 1 can be detachably assembled on the bottom shell 2. The connector shielding shell also includes a vertical partition plate 4, which is set between the top shell 1 and the bottom shell 2 and extends along the longitudinal direction Y and the height direction Z of the connector shielding shell. The vertical partition plate 4 is used to separate the space between the top shell 1 and the bottom shell 2 into multiple chambers 103 arranged side by side in the transverse direction X of the connector shielding shell. In the illustrated embodiment, the connector shielding shell has a single layer of chambers 103.

The top shell 1 also has two first side walls 11 opposite to each other in the transverse direction X of the connector shielding shell, and a first connection column 110 is formed on each of the two first side walls 11. The bottom shell 2 includes a bottom wall and two second side walls 21 opposite to each other in the transverse direction X of the connector shielding shell, and a second connection column 210 is formed on each of the two second side walls 21. A threaded hole 102 is formed in each of the first connection column 110 and the second connection column 210, so that the top shell 1 and the bottom shell 2 can be tightened together by a screw (not shown) screwed into the threaded holes 102.

A first convex rib 12 extending along the longitudinal direction Y of the connector shielding shell is formed on the inner side of the top shell 1. A second convex rib 22 extending along the longitudinal direction Y of the connector shielding shell is formed on the inner side of the bottom shell 2. The first convex rib 12 and the second convex rib 22 are located in the middle of the transverse direction X of the connector shielding shell, and a threaded hole 102 is formed on each of the first convex rib 12 and the second convex rib 22, so that the top shell 1 and the bottom shell 2 can be tightened together by a screw (not shown) screwed into the threaded holes 102. In this way, the top shell 1 and bottom shell 2 can be more reliably fixed together to prevent separation in the middle of the top shell 1 and bottom shell 2.

In the illustrated embodiments, insertion slots 104 extending along the longitudinal direction Y of the connector shielding shell are formed on the inner sides of the top shell 1 and the bottom shell 2, respectively. The upper and lower sides of the vertical partition plate 4 are respectively inserted into the insertion slots 104 on the top shell 1 and the bottom shell 2 to fix the vertical partition plate 4 to the top shell 1 and the bottom shell 2.

Multiple contact protrusions 14 are formed on the inner sides of the top wall 10 of the top shell 1. The multiple contact protrusions 14 are respectively located in multiple chambers 103 for thermal contact with the mating connectors inserted in the chambers 103.

The connector shielding shell further comprises multiple spring sheets 7. The spring sheets 7 are respectively arranged in multiple chambers 103 and fixed to the inner side of the bottom shell 2. The spring sheet 7 is used to apply a pushing force on the mating connector inserted into the chamber 103 to ensure reliable thermal contact between the mating connector and the contact protrusion 14.

The chamber 103 has an insertion port that allows for the insertion of the mating connector. The connector shielding shell also includes a shielding spring 5, which is installed on the peripheral wall of the insertion port 103 of the chamber 103 and is used for electrical contact with the shielding shell of the mating connector.

In another exemplary embodiment of the present disclosure, a connector shielding shell assembly is also disclosed. The connector shielding shell assembly includes the aforementioned connector shielding shell and a cooling pipe 6. The cooling pipe 6 is installed in the installation hole 101′ of the connector shielding shell.

A connector is also disclosed. The connector includes the aforementioned connector shielding shell assembly and multiple terminal modules. The multiple terminal modules are respectively installed in multiple chambers 103 of the connector shielding shell for mating and connecting with the mating connectors inserted into the chambers 103.

In addition, those areas in which it is believed that those of ordinary skill in the art are familiar, have not been described herein in order not to unnecessarily obscure the invention described. Accordingly, it must be understood that the invention is not to be limited by the specific illustrative embodiments, but only by the scope of the appended claims.

It should be appreciated for those skilled in this art that the above embodiments are intended to be illustrated, and not restrictive. For example, many modifications may be made to the above embodiments by those skilled in this art, and various features described in different embodiments may be freely combined with each other without conflicting in configuration or principle.

Although several exemplary embodiments have been shown and described, it would be appreciated by those skilled in the art that various changes or modifications may be made in these embodiments without departing from the principles and spirit of the disclosure, the scope of which is defined in the claims and their equivalents.

As used herein, an element recited in the singular and proceeded with the word “a” or “an” should be understood as not excluding plural of the elements or steps, unless such exclusion is explicitly stated. Furthermore, references to “one embodiment” of the present disclosure are not intended to be interpreted as excluding the existence of additional embodiments that also incorporate the recited features. Moreover, unless explicitly stated to the contrary, embodiments “comprising” or “having” an element or a plurality of elements having a particular property may include additional such elements not having that property.

What is claimed is:

1. A connector shielding shell, comprising:
a bottom shell; and
a top shell including a top wall having a predetermined thickness, the top wall having an installation opening formed on or in the top wall of the top shell and adapted to receive a cooling pipe, the top shell defining a cooling plate adapted to transfer heat to the cooling pipe.

2. The connector shielding shell according to claim 1, wherein:
the thickness of the top wall of the top shell is greater than the diameter of the cooling pipe, and the installation opening comprises an installation slot formed on the outer surface of the top wall of the top shell, the installation slot extends along a transverse direction of the connector shielding shell; and
the cross-section of the installation slot is U-shaped, and the depth of the installation slot is not less than a diameter of the cooling pipe, so that the cooling pipe can be completely received in the installation slot in a depth direction of the slot.

3. The connector shielding shell according to claim 2, wherein:
the top shell is detachably assembled on the bottom shell; and
the connector shielding shell further comprises a vertical partition plate arranged between the top shell and the bottom shell and extends along a longitudinal direction and a height direction of the connector shielding shell, the vertical partition plate divides a space between the top shell and the bottom shell into multiple chambers arranged side by side in the transverse direction of the connector shielding shell.

4. The connector shielding shell according to claim 3, wherein:
the top shell includes two first side walls opposite to each other in the transverse direction of the connector shielding shell, and a first connection column is formed on each of the two first side walls;
the bottom shell comprises a bottom wall and two second side walls opposite to each other in the transverse direction of the connector shielding shell, and a second connection column is formed on each of the two second side walls; and
a threaded hole is formed in each of the first connection column and the second connection column, so that the top shell and the bottom shell can be tightened together by a screw screwed into the threaded hole.

5. The connector shielding shell according to claim 4, wherein
a first convex rib extending along the longitudinal direction of the connector shielding shell is formed on an inner side of the top shell;
a second convex rib extending along the longitudinal direction of the connector shielding shell is formed on an inner side of the bottom shell;
the first convex rib and the second convex rib are arranged in a middle of the transverse direction of the connector shielding shell; and
a threaded hole is formed in each of the first convex rib and the second convex rib such that the top shell and the bottom shell are adapted to be fastened together by a screw screwed into the threaded hole.

6. The connector shielding shell according to claim 3, wherein:
an insertion slot extending along the longitudinal direction of the connector shielding shell is formed on an inner side of each of the top shell and the bottom shell; and
upper and lower sides of the vertical partition plate are respectively inserted into the insertion slots on the top shell and the bottom shell to fix the vertical partition plate to the top shell and the bottom shell.

7. The connector shielding shell according to claim 3, further comprising multiple thermal conductive components respectively arranged in respective ones of the multiple chambers and welded to an inner side of the top shell, the thermal conductive component protrudes a predetermined height from the inner side of the top shell for thermal contact with a mating connector inserted into the chamber.

8. The connector shielding shell according to claim 3, wherein:
the thickness of the top wall of the top shell is greater than the diameter of the cooling pipe; and
an installation hole extending along the transverse direction of the connector shielding shell is formed in the top wall of the top shell, and the cooling pipe is inserted into the installation hole.

9. The connector shielding shell according to claim 3, wherein multiple contact protrusions are formed on the inner side of the top wall of the top shell and are arranged in respective ones of the multiple chambers for thermal contact with the mating connectors inserted in the chambers.

10. The connector shielding shell according to claim 9, further comprising multiple spring sheets which are respectively arranged in the multiple chambers and fixed to the inner side of the bottom shell, each of the spring sheets is adapted to apply a pushing force on the mating connector inserted into the chamber to ensure reliable thermal contact between the mating connector and the contact protrusion.

11. The connector shielding shell according to claim 1, further comprising an intermediate shell arranged between the top shell and the bottom shell and separating a space between the top shell and the bottom shell into adjacent multi-layer spaces in the height direction of the connector shielding shell, the intermediate shell having a horizontal partition wall that separates adjacent two layers of space, and an installation slot or installation hole is formed on or in the horizontal partition wall of the intermediate shell for installing a cooling pipe, the intermediate shell defining a cooling plate adapted to transfer heat to the cooling pipe.

12. The connector shielding shell according to claim 11, wherein:
a thickness of the horizontal partition wall of the intermediate shell is greater than the diameter of the cooling pipe, and an installation slot extending along the transverse direction of the connector shielding shell is formed on the horizontal partition wall of the intermediate shell; and
the cross-section of the installation slot is U-shaped, and a depth of the installation slot is not less than the diameter of the cooling pipe, so that the cooling pipe can be completely buried in the installation slot.

13. The connector shielding shell according to claim 11, wherein:
the top shell, the intermediate shell, and the bottom shell are detachably assembled together by stacking to form a multi-layer space; and
the connector shielding shell further includes a vertical partition plate arranged in each layer of the multi-layer space and extends along the longitudinal direction and the height direction of the connector shielding shell, the vertical partition plate divides each layer of space into multiple chambers arranged side by side in the transverse direction of the connector shielding shell.

14. The connector shielding shell according to claim 13, wherein:
the top shell includes two first side walls opposite to each other in the transverse direction of the connector shielding shell, a first connection column is formed on each of the two first side walls;
the bottom shell includes a bottom wall and two second side walls opposite to each other in the transverse direction of the connector shielding shell, a second connection column is formed on each of the two second side walls;
the intermediate shell has two third side walls opposite to each other in the transverse direction of the connector shielding shell, a third connection column is formed on each of the two third side walls; and
a threaded hole is formed in each of the first connection column, the second connection column and the third connection column and the top shell, the bottom shell and the intermediate shell are adapted to be fastened together by screws arranged in the threaded holes.

15. The connector shielding shell according to claim 14, wherein:
a first convex rib extending along the longitudinal direction of the connector shielding shell is formed on an inner side of the top shell;
a second convex rib extending along the longitudinal direction of the connector shielding shell is formed on an inner side of the bottom shell;
a third convex rib extending along the longitudinal direction of the connector shielding shell is formed on an inner side of the intermediate shell;
the first convex rib, the second convex rib, and the third convex rib are arranged in a middle of the transverse direction of the connector shielding shell; and
a threaded hole is formed in each of the first convex rib, the second convex rib and the third convex rib such that the top shell, the bottom shell and the intermediate shell are adapted to be fastened together by screws arranged in the threaded holes.

16. The connector shielding shell according to claim 13, wherein an insertion slot extending along the longitudinal direction of the connector shielding shell is formed on an inner side of each of the top shell, the bottom shell and the intermediate shell, the side edges of the vertical partition plate are inserted into the insertion slots to fix the vertical partition plate.

17. The connector shielding shell according to claim 13, further comprising multiple thermal conductive components arranged in respective multiple chambers of the connector shielding shell, wherein:
the thermal conductive components located in a top layer of chambers are welded to the inner side of the top shell and protrude at a predetermined height from the inner side of the top shell for thermal contact with mating connectors inserted into the top chambers; and
the thermal conductive components located in other chambers except for the top layer of chambers are welded to the inner side of the intermediate shell facing the bottom shell and protrude at a predetermined height from the inner side of the intermediate shell for thermal contact with mating connectors inserted into other chambers.

18. The connector shielding shell according to claim 3, wherein each of the chambers has an insertion port that allows for the insertion of the mating connector.

19. The connector shielding shell according to claim 18, wherein the connector shielding shell further includes a shielding spring installed on a peripheral wall of the insertion port of the chamber for electrical contact with a shielding shell of the mating connector.

20. A connector shielding shell assembly, comprising:
a connector shielding shell, including:
a bottom shell; and
a top shell including a top wall having a predetermined thickness, the top wall defining an installation opening formed on or in the top wall of the top shell and adapted to receive a cooling pipe, and the top shell defining a cooling plate adapted to transfer heat to the cooling pipe; and
a cooling pipe installed in the installation opening of the connector shielding shell.
